(19) United States
(12) Patent Application Publication
(10) Pub. No.: US 2011/0141760 A1
(43) Pub. Date: Jun. 16, 2011

(54) LUMINOUS INTERIOR TRIM ELEMENT, AND CORRESPONDING DOOR AND MOTOR VEHICLE

(75) Inventors: Daniel Ory, Meru (FR); Claudiu Vasilescu, Meru (FR); Dany Desrus, Nanterre (FR); Jurgen Griebel, Maulburg (DE); Yannick Gouedard, Basel (CH)

(73) Assignee: FAURECIA INTERIEUR INDUSTRIE, NANTERRE (FR)

(21) Appl. No.: 12/995,166

(22) PCT Filed: May 22, 2009
(86) PCT No.: PCT/FR2009/050951

§ 371 Date: Mar. 4, 2011

(30) Foreign Application Priority Data
May 29, 2008 (FR) 08 53549

(51) Int. Cl. F21S 8/10; H01L 33/02; F21V 8/00

(52) U.S. Cl. 362/555; 362/519; 362/551

(57) ABSTRACT

A trim element (1) of the invention comprises: a first wall (2) enabling the passage of light with an outer surface (3) intended to be visible from the passenger compartment (4) of the motor vehicle; a second wall (8) defining a space (9) with the first wall (2) and one surface (7) of which is capable of reflecting light rays; and a luminous element (6) positioned inside the space (9) so as to backlight the first wall (2). The luminous element (6) sends a beam of light rays (L) to the second wall (8). The surface (7) diffusely reflects light rays. An inner surface (11) of the first wall (2) has light-reflecting properties such that the incident light rays on said inner surface (11) are partially reflected to the second wall (8) and partially emitted across the first wall (2).

This invention relates to a luminous interior trim element, namely for motor vehicles, comprising:
a first wall letting pass light, this first wall having an outer surface intended to be visible from the passenger compartment of the motor vehicle,
a second wall defining a space with the first wall, and one surface of the second wall opposite the first wall is capable of reflecting light rays, and
a lighting device comprising a luminous element positioned inside the space so as to backlight the first wall.

Such a luminous interior trim element is known from document FR 2 877 896 A1. Document WO 2007/003 663 A1 gives another example of a luminous interior trim element.

The luminous interior trim element known from document FR 2 877 896 A1 allows for lighting the passenger compartment of a motor vehicle. Lighting is ensured by a light source arranged inside a casing. The casing comprises a back wall and a wall oriented toward the passenger compartment. The light source is arranged for the light rays to be emitted inside the casing and undergo at least one reflection on the back wall in order to then pass through the front wall. For this purpose, the light source is arranged inside the casing so that the light flux is substantially tangent to the back wall, and this back wall is arranged to allow for the light flux to be reflected toward the front wall.

However, in such an arrangement, lighting of the passenger compartment of the vehicle is not always homogeneous and/or sufficient. Indeed, under certain circumstances, the front wall is not homogeneously backlit over the whole length of the casing. The light flux being substantially tangent to the back wall, only some of the light rays intercept the back wall and are reflected thereby.

Therefore, it is an objective of the invention to provide a luminous interior trim element ensuring better illumination of the passenger compartment of a motor vehicle. In particular, backlighting is to be obtained, which is visually homogeneous and uniform or progressive.

This objective is attained with a trim element of the type mentioned above, characterized in that the luminous element is capable of sending a beam of light rays mainly toward the second wall, in that the surface of the second wall opposite the first wall is capable of diffuse reflection of the light rays, and in that the inner surface of the first wall, opposite the outer surface, has light-reflecting properties so that the light rays incident on this inner surface are partially reflected toward the second wall, and partially transmitted through the first wall toward the passenger compartment.

By arranging the luminous element so that the light rays are substantially sent toward the second wall, intending the surface of the second wall to reflect light in a diffuse manner, and by making the inner surface of the first wall partially reflecting, light will undergo multiple reflections between the two walls and propagate throughout the entire space, even in areas remote from the luminous element, before leaving the same through the first wall. Thus, the entire length of the first wall is homogeneously backlit.

According to specific embodiments, the trim element comprises one or more of the following characteristics, either taken individually or according to any technically possible combination:
the luminous element is adapted to send the beam of light rays mainly in one direction forming an angle between 1 and 90° with the plane containing the barycenter of the luminous element and the joining segment between the surface of the second wall and the inner surface of the first wall;
the angle lies between 1 and 30°;
the surface of the second wall is a near-Lambertian diffusing reflector,
the light-reflecting properties of the inner surface are such that according to the CIE 1976 (L*, a*, b*) (CIELAB) color space, luminance L* thereof is strictly speaking greater than 60;
the inner surface of the first wall reflects light in a diffuse manner, preferably in a near-Lambertian manner;
the surface comprises a reflective coating;
the surface of the second wall and/or the inner surface of the first wall are at least partially provided with asperities forming a pattern adapted to disperse by reflection light rays incident on this pattern;
the asperities are formed by a set of protruding geometric elements distributed over at least one part of the surface and/or the surface;
the surface of each of a plurality of protruding geometric elements is provided with protruding elements;
the luminous element extends over at least one part of the periphery of the space;
the luminous element is a cylindrical light guide, such as an optical fiber;
the lighting device comprises a light source, such as a light-emitting diode (LED), connected to the luminous element;
the luminous element comprises reliefs creating optical interferences; and
the outer surface of the first wall comprises a porous coating, namely a porous fabric, the pores of this coating letting light rays pass.

Also an object of the invention is a motor vehicle door comprising a trim element as described above, as well as a motor vehicle comprising a trim element as described above.

The invention will be better understood by the following review of the description, provided only by way of example, and given with reference to the enclosed drawings.

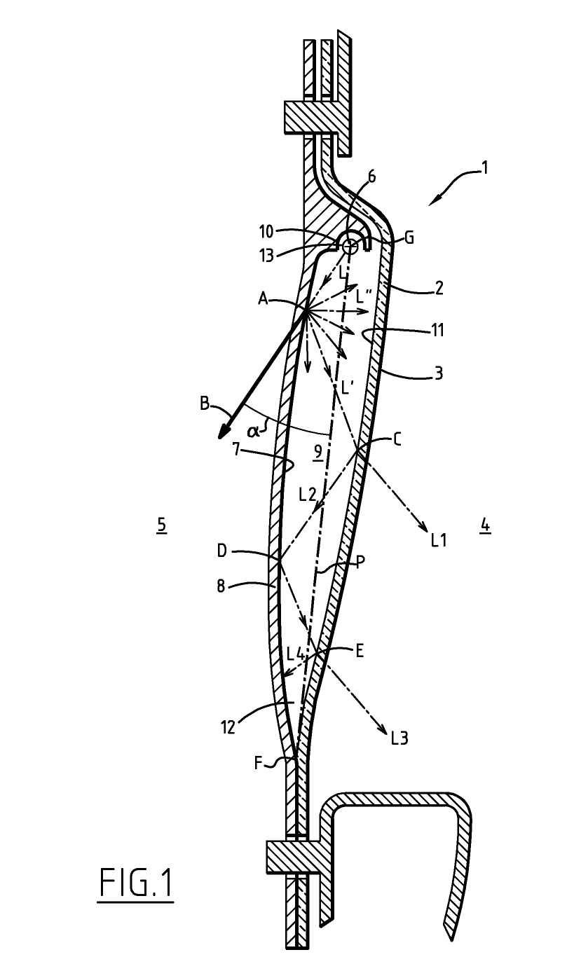

FIG. 1 is a transverse sectional view of a trim element according to an embodiment of the invention;

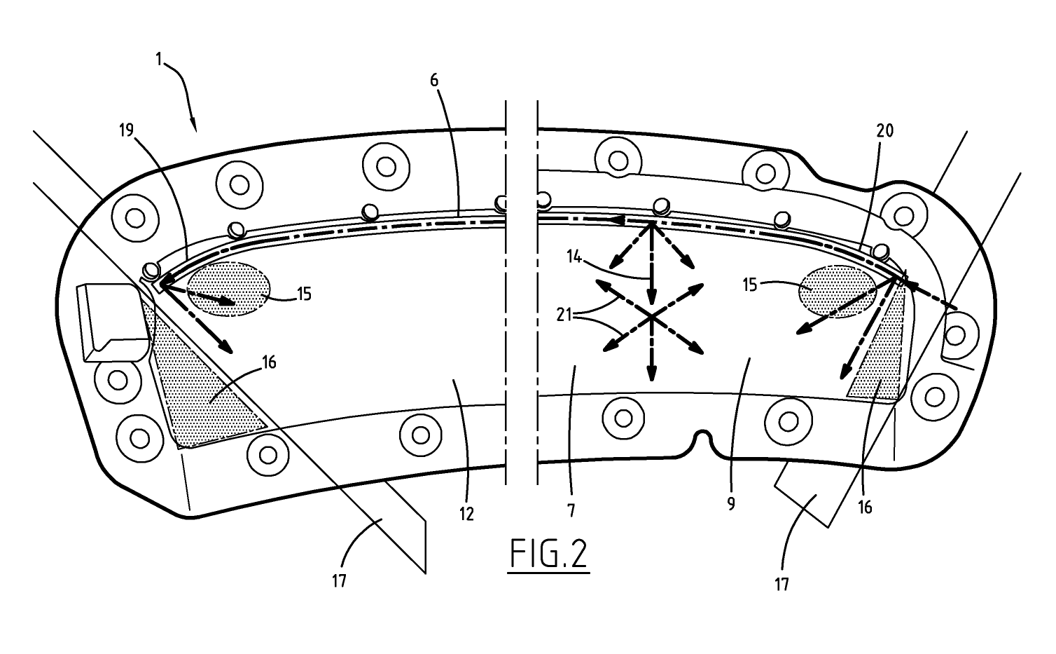

FIG. 2 is a front view of the trim element of FIG. 1, with the first wall, which is intended to be visible from the passenger compartment, being omitted; and

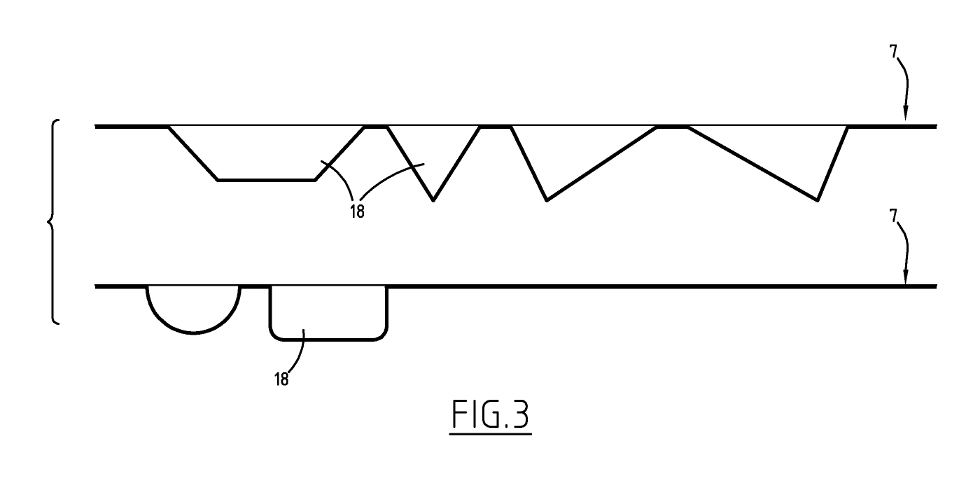

FIG. 3 shows in detail several embodiments of the protruding geometric elements, which may cover the surfaces of the trim element of FIGS. 1 and 2.

FIG. 1 illustrates a motor vehicle door panel, which is provided with a trim element 1, and which separates the passenger compartment 4 from the outside 5 of the motor vehicle. The main function of the trim element 1 is to provide background lighting for the passenger compartment 4, wherein the lighting is to be uniform or progressive (e.g. gently decreasing along a given direction of the trim element).

The interior trim element 1 according to FIG. 1 has two lateral walls 2, 8 defining therebetween a closed space 9. A light guide 6, having a cylindrical shape in the example described, is arranged inside the closed space 9. More specifically, the cylindrical light guide 6, according to FIG. 1, is located in a corner 13 at the upper end of the closed space 9.

The light guide 6 is composed of transparent or translucent material. It extends over all or part of the periphery 10 of the closed space 9.

The cylindrical light guide 6, which in particular may be an optical fiber, is connected to a light source, such as a light-emitting diode (LED).

The light source may also be of a different kind. It may be a lamp, such as an incandescent lamp.

Alternatively, light may also be generated by a plurality of light sources, e.g. from one to three. It is also possible to provide a plurality of light guides.

Alternatively, instead of a light guide 6, it is also possible to provide a strip of an electroluminescent film.

The wall 2 is made so as to let light pass. For this purpose, the wall 2 may be translucent, transparent, or porous. It is wall 2 which is visible from the passenger compartment 4 when the trim element 1 is integrated for instance into the door of a motor vehicle.

Alternatively, the wall 2 of the trim element 1 may comprise an outer coating. The coating has pores letting light pass. The coating may also adopt other shapes, with the coating however remaining light-permeable.

The wall 2 has an inner surface 11, i.e. it is arranged toward the inside of the trim element 1 as opposed to the outside thereof. The inner surface 11 is partially reflective and partially permeable, i.e. it lets part of incident light pass, whereas another part is reflected toward wall 8.

Preferably, the inner surface 11 has light-reflecting properties such that according to the CIE 1976 (L*, a*, b*) (CIELAB) color space, luminance L* thereof is strictly speaking greater than 60, and preferably greater than 70.

Thus, the wall 2 is not completely light-permeable, but will reflect the same partially, which allows to make sure that one part of the light, before leaving the closed space 9, will reach by multiples reflections the areas of the closed space 9 which are remote from the light guide 6.

Alternatively, the inner surface 11 may have light-diffusing properties, i.e. incident light is reflected in multiple directions rather than in one direction only. In particular, this diffuse reflection may be of the near-Lambertian kind. Such a diffuse reflection will provide better homogenization of light distribution inside space 9.

As for the other wall 8, it is opaque. The inner surface 7 thereof defines the closed space 9 and is adapted to reflect light rays in a diffuse manner. For this purpose, the inner surface 7 may be covered with a material having such optical properties. The material may be painted or deposited on the surface 7 by another method. Thus, surface 7 reflects light in a diffuse manner, still in view of homogenizing illumination. Preferably, the surface 7 is a near-Lambertian diffusing reflector.

Similarly to surface 11, surface 7 may have light-reflecting properties such that according to the CIE 1976 (L*, a*, b*) (CIELAB) color space, luminance L* thereof is strictly speaking greater than 60, and preferably greater than 70.

The light produced by the source is guided by the cylindrical light guide 6 that it leaves laterally, due to reliefs provided so as to create optical interferences on the inner surface of the light guide 6. When hitting such reliefs, the light escapes laterally from the light guide 6, as represented in the figure by ray L.

The light guide 6 emits light inside space 9 preferably in a main direction B. This direction B forms an angle α with the plane P containing the barycenter G of the light guide 6 and the joining segment F between the surface 7 of the second wall 8 and the inner surface 11 of the first wall 2.

With reference to FIG. 1, the joining segment F is the contact point between the surfaces 7 and 11 at the lower end of space 9. Segment F delimits the lower part of space 9. In FIG. 1, segment F merely consists of one point, as FIG. 1 represents a cross-section of the trim element.

The angle α may lie between 1 and 90°, but preferably lies between 1 and 30°.

A light ray L coming from the light source and intercepting the inner surface 7 in a point A undergoes multiple reflections. Upon interception of ray L in point A, a multitude of light rays L″, including ray L′, are reemitted in all directions opposite to surface 7 toward the closed space 9, e.g. totally or partially according to Lambert's law.

Ray L′ intercepts surface 11 in point C. Hitting the inner surface 11 of wall 2 in point C, ray L′ is split into two components, namely rays L1 and L2. Ray L1 passes through wall 2, while being refracted, so as to then light the inside of the passenger compartment 4. Ray L2 corresponds to the reflected component, which then will hit surface 7 in point D so as to exhibit a behavior similar to that of ray L in point A. In the point of impact E on surface 11, ray L2 is divided into two rays L3 and L4, like ray L before. The other rays L″ also intercept the surface 11 and have a behavior similar to that of ray L′ described before.

FIG. 2 shows the trim element 1 in a front view, as it can be seen by a passenger located inside the passenger compartment 4, except that the first wall 2 has been removed so that the inside of the closed space 9 can be seen.

The light guide 6 extends over the entire upper periphery of the closed space 9 and has some curvature. This curvature is particularly strong at the ends 19 and 20 of the light guide 6. Light is injected at end 20 and leaves the light guide 6 toward the lower edge 12 of the trim element 1, as is shown by the arrows of FIG. 2. In particular, arrow 14 is a beam of light rays moving toward surface 7 to be then diffused thereby, i.e. returned in a plurality of directions indicated by arrows 21.

Due to the strong curvature, at the ends 19 and 20, the light will leave the light guide 6 according to a plane 17. The result is that the light will not reach the areas 16 of the closed space 9 sufficiently and is at the same time focused on areas 15 of this space 9. If it is not modified, this heterogeneous distribution of the light will create dark spots and bright spots on the visible surface of the trim element. Such spots make the backlighting generated by the trim element 1 unpleasant. They are avoided by adding asperities at the relevant areas 15 and 16 of surface 7.

Such asperities are preferably formed by a set of protruding geometric elements. Thereby, a relief is obtained, which is made so that it will redistribute the light of the excessively illuminated areas 15 to the poorly illuminated areas 16. Thus, the back-lighting provided by the trim element 1 is homogenized and the formation of unpleasant spots is prevented.

FIG. 3 gives several examples of protruding geometric elements 18, which may cover the areas 15 and 16. Elements 18 may have a wide variety of shapes. As is shown in FIG. 3, the cross-section thereof may for instance have the shape of a trapezoid, a triangle, a semi-circle, or a rounded rectangle.

With the trim element, which has just been described, the illumination of the passenger compartment 4 is homogenized and improved, namely with a reduced number of light sources. Indeed, due to multiple partial reflections at the wall 2, and due to the diffusing properties of surface 7, light is distributed throughout the volume of space 9 and will leave the same over the entire length of wall 2. Thus, as seen from the passenger compartment 4, wall 2 emits a uniform radiation over the whole apparent surface thereof.

In certain variants, it is possible not to use asperities on surface 7 of the trim element 1.

1. A luminous interior trim element for motor vehicles, comprising:
a first wall that lets light pass, the first wall comprising an outer surface intended to be visible from a passenger compartment of the motor vehicle,
a second wall that delimits a space between the first wall and the second wall, wherein a surface of the second wall opposite the first wall is capable of reflecting light rays, and
a lighting device comprising a luminous element positioned inside the space so as to backlight the first wall.
wherein the luminous element is capable of sending a beam of light rays (L) mainly to the second wall, wherein the surface of the second wall opposite the first wall is capable of reflecting light rays in a diffuse manner, and wherein the inner surface of the first wall, opposite an outer surface of the first wall, has light-reflecting properties such that light rays incident on the this inner surface are partially reflected toward the second wall, and partially transmitted through the first wall toward the passenger compartment.

2. The trim element according to claim 1, wherein the luminous element is adapted to send the beam of light rays (L) mainly in one direction (B) forming an angle (α) between 1 and 90° with a plane (P) containing a barycenter (G) of the luminous element and a joining segment (F) between the surface of the second wall and the inner surface of the first wall.

3. The trim element according to claim 2, wherein the angle (α) is between 1 and 30°.

4. The trim element according to claim 1, wherein the surface of the second wall is a near-Lambertian diffusing reflector.

5. The trim element according to claim 1, wherein the light-reflecting properties of an inner surface of the second wall are such that according to the CIE 1976 (L*, a*, b*) (CIELAB) color space, luminance L* thereof is greater than 60.

6. The trim element according to claim 1, wherein the inner surface of the first wall reflects light in a diffuse manner.

7. The trim element according to claim 1, wherein the surface of the second wall comprises a reflective coating.

8. The trim element according to claim 1, wherein the surface of the second wall and/or the inner surface of the first wall are at least partially provided with asperities in a pattern adapted to disperse by reflection light rays incident on the pattern.

9. The trim element according to claim 8, wherein the asperities are formed by a set of protruding geometric elements distributed over at least one part of the surface of the second wall and/or the inner surface of the first wall.

10. The trim element according to claim 9, wherein the surface of each of a plurality of protruding geometric elements is provided with protruding elements.

11. The trim element according to claim 1, wherein the luminous element extends over at least one part of a periphery of the space.

12. The trim element according to claim 1, wherein the luminous element is a cylindrical light guide.

13. The trim element according to claim 1, wherein the lighting device comprises a light source connected to the luminous element.

14. The trim element according to claim 1, wherein the luminous element comprises reliefs that create optical interferences.

15. The trim element according to claim 1, wherein the outer surface of the first wall comprises a porous coating, wherein pores of the coating let light rays (L1, L3) pass.

16. A motor vehicle door comprising a trim element according to claim 1.

17. A motor vehicle comprising a trim element according to claim 1.

18. The trim element of claim 6, wherein the inner surface of the first wall reflects light in a near-Lambertian manner.

19. The trim element of claim 12, wherein said luminous element is an optical fiber.

20. The trim element of claim 13, wherein the light source is a light-emitting diode (LED).

21. The trim element of claim 15, wherein the porous coating is a porous fabric.
